(19) United States
(12) Patent Application Publication
(10) Pub. No.: US 2025/0035563 A1
(43) Pub. Date: Jan. 30, 2025

(54) SEMICONDUCTOR MEASUREMENT DEVICE

(71) Applicant: Samsung Electronics Co., Ltd., Suwon-si (KR)

(72) Inventors: Ryuju Sato, Yokohama (JP); INGI KIM, Suwon-si (KR)

(21) Appl. No.: 18/764,677

(22) Filed: Jul. 5, 2024

(30) Foreign Application Priority Data
Jul. 25, 2023 (JP) 2023-120611
Dec. 18, 2023 (KR) 10-2023-0185078

(51) Int. Cl. G01N 21/95; G01N 21/88

(52) U.S. Cl. CPC G01N 21/95; G01N 21/8806

(57) ABSTRACT

A semiconductor measurement device includes a laser light source generating a fundamental wave having a first wavelength, an objective lens focusing the fundamental wave on a sample surface of a sample, a wavelength filter blocking reflected light corresponding to the fundamental wave that is reflected from the sample surface and transmitting signal light generated by irradiating the fundamental wave to the sample surface, and a first detection unit detecting the signal light passing through the wavelength filter. The first detection unit is located to detect the signal light generated from the sample surface and measures an intensity distribution of the signal light emitted in two or more different emission directions from the sample surface of the sample placed at a fixed position. The signal light includes nonlinear light generated from the sample surface irradiated by the fundamental wave and having a second wavelength which is different from the first wavelength.

### CROSS-REFERENCE TO RELATED APPLICATION

This application is based on and claims priority under 35 USC § 119 to Japanese Patent Application No. 2023-120611, filed on Jul. 25, 2023, in the Japanese Patent Office and Korean Patent Application No. 10-2023-0185078, filed on Dec. 18, 2023, in the Korean Intellectual Property Office, the disclosures of each of which are incorporated by reference herein in their entireties.

### BACKGROUND

The inventive concept relates to semiconductor measurement devices.

In the field of manufacturing semiconductor devices, the only axis of evolution was the miniaturization of circuit patterns until about 20 years ago, and in addition to improving driving speed and reducing power consumption, lower costs were achieved through miniaturization. However, as a technical difficulty of miniaturization has increased, the contribution of performance improvement has recently been particularly increased by controlling physical properties, such as improving electron mobility, by introducing new materials, such as high-K and low-K dielectric materials, or intentionally adding deformation in addition to three-dimensional (3D) structuring of devices. Due to these factors, high-precision and high-throughput physical property measurement has become essential for both process establishment in research and development and improvement of yield during mass production. For example, there are measurements of the amount and spatial distribution of dopants in an ion implantation process, a reactivation state after annealing, and internal deformation in a selective epitaxial growth process of silicon germanium (SiGe). The following documents are patent documents and nonpatent documents related to measurement. Patent Document 1: Japanese Application Publication No. 04-340404, Patent Document 2: Specification of U.S. Pat. No. 6,788,405, Patent Document 3: Specification of U.S. Pat. No. 5,557,409, Patent Document 4: Specification of U.S. Pat. No. 7,158,284, Patent Document 5: U.S. Application Publication No. 2015/330908, Patent Document 6: Japanese Application Publication No. 2021-085698, NonPatent Document 1: BLOEMBERGEN, N. et. al., Light Waves at the Boundary of Nonlinear Media, Phys. Rev. 128, 606 (1962) Nonpatent Document 2: Guidotti, D. et. al, Second harmonic generation in centro-symmetric semiconductors, Solid state communications 46.4 (1983): 337-340.

### SUMMARY

The inventive concept provides a semiconductor measurement device capable of improving measurement precision.

In addition, the problem to be solved by the technical idea of the inventive concept is not limited to the problems mentioned above, and other problems and new features may be clearly understood by those skilled in the art from the description below.

According to an aspect of the present disclosure, a semiconductor measurement device includes a laser light source configured to generate a fundamental wave having a first wavelength, an objective lens configured to focus the fundamental wave on a sample surface of a sample, a wavelength filter configured to block reflected light corresponding to the fundamental wave that is reflected from the sample surface and transmit signal light generated by irradiating the fundamental wave to the sample surface, and a first detection unit configured to detect the signal light passing through the wavelength filter. The first detection unit is located to detect the signal light generated from the sample surface and measures an intensity distribution of the signal light emitted in two or more different emission directions from the sample surface of the sample placed at a fixed position. The signal light includes nonlinear light generated from the sample surface irradiated by the fundamental wave and having a second wavelength which is different from the first wavelength.

According to an aspect of the present disclosure, a semiconductor measurement device includes a laser light source configured to generate a fundamental wave, which is a pulse-type fundamental wave, having a first wavelength, an objective lens configured to focus the fundamental wave on a sample surface of a sample, an annular light shaper located between the laser light source and the objective lens at an optical path of the fundamental wave and configured to shape the fundamental wave into an annular shape, a delay generator located between the laser light source and the objective lens at the optical path of the fundamental wave and configured to generate a time difference between when a part of the fundamental wave reaches the sample surface and when another part of the fundamental wave reaches the sample surface, a polarization controller located between the laser light source and the objective lens at the optical path of the fundamental wave and configured to control a polarization state of the fundamental wave, a wavelength filter configured to block reflected light corresponding to the fundamental wave that is reflected from the sample surface and transmit signal light generated by irradiating the fundamental wave to the sample surface, and a detection unit including a detector located at a conjugate position of a pupil plane of the objective lens and configured to detect the signal light transmitted by the wavelength filter. The detection unit is located to detect the signal light generated from the sample surface and measures an intensity distribution of the signal light emitted in two or more different emission directions from the sample surface of the sample placed at a fixed position. The signal light includes nonlinear light generated from the sample surface irradiated by the fundamental wave and having a second wavelength which is different from the first wavelength.

According to an aspect of the present disclosure, a semiconductor measurement device includes a laser light source configured to generate a fundamental wave, which is a pulse-type fundamental wave, having a first wavelength, an objective lens configured to focus the fundamental wave on a sample surface of a sample, a polarization controller located between the laser light source and the objective lens at an optical path of the fundamental wave and configured to control a polarization state of the fundamental wave, a wavelength filter configured to block reflected light corresponding to the fundamental wave that is reflected from the sample surface and transmit signal light generated by irradiating the fundamental wave to the sample surface and having a second wavelength that is different from the first wavelength, and a detection unit including a detector located at a conjugate position of a pupil plane of the objective lens and detecting the signal light transmitted by the wavelength filter. The detection unit is located to detect the signal light generated from the sample surface and measures an intensity distribution of the signal light emitted in two or more different emission directions from the sample surface of the sample placed at a fixed position. The signal light includes nonlinear light generated from the sample surface irradiated by the fundamental wave.

### BRIEF DESCRIPTION OF THE DRAWINGS

Embodiments will be more clearly understood from the following detailed description taken in conjunction with the accompanying drawings in which:

FIG. 1 is a configuration diagram schematically illustrating a semiconductor measurement device according to an embodiment;

FIG. 2 is a two-dimensional (2D) image illustrating components of a second harmonic for each azimuth detected by a detector located at a conjugate position on a pupil plane of an objective lens in the semiconductor measurement device of FIG. 1;

FIG. 3 is a flowchart illustrating a semiconductor measurement method using the semiconductor measurement device of FIG. 1 according to an embodiment;

FIG. 4 is a configuration diagram illustrating a semiconductor measurement device according to an embodiment;

FIG. 5 is a diagram illustrating a cross-section orthogonal to an optical axis of a fundamental wave formed by an annular light shaper in the semiconductor measurement device of FIG. 4;

FIG. 6 is a perspective view illustrating a delay generator having a distribution in the thickness of a fundamental wave in an optical axis direction in the semiconductor measurement device of FIG. 4;

FIG. 7 is a configuration diagram illustrating a semiconductor measurement device according to an embodiment;

FIG. 8 is a diagram illustrating the time difference between fundamental waves generated by a delay generator in the semiconductor measurement device of FIG. 7;

FIG. 9 is a configuration diagram illustrating a semiconductor measurement device according to an embodiment;

FIG. 10 is a flowchart illustrating a semiconductor measurement method using the semiconductor measurement device of FIG. 9;

FIG. 11 is a configuration diagram showing a semiconductor measurement device according to a reference example;

FIG. 12 is a diagram showing an azimuthal dependence detected by a detector in the semiconductor measurement device of FIG. 11;

FIG. 13 is a diagram showing a configuration of the semiconductor measurement device of FIG. 11 when the field of view is shifted;

FIG. 14 is a diagram illustrating the configuration of the semiconductor device of FIG. 9 when the field of view is shifted;

FIG. 15 is a configuration diagram illustrating a semiconductor measurement device according to an embodiment;

FIG. 16 is a perspective view illustrating a delay generator in the semiconductor measurement device of FIG. 15;

FIG. 17 is a configuration diagram illustrating a semiconductor measurement device according to an embodiment;

FIG. 18 is a configuration diagram illustrating a semiconductor measurement device according to an embodiment;

FIG. 19 is a configuration diagram illustrating a light splitting unit in the semiconductor measurement device of FIG. 18;

FIG. 20 is a diagram illustrating an intensity distribution at a position of a pupil plane of a fundamental wave split by a light splitting unit in the semiconductor measurement device of FIG. 18; and

FIG. 21 is a configuration diagram illustrating a semiconductor measurement device according to an embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted. For clarity of description, appropriate omissions and simplifications are made in the following description and drawings, and redundant descriptions are omitted as necessary. Some symbols and hatching are omitted so as not to complicate the drawings.

It may be difficult to evaluate measurement of physical properties regarding the amount and spatial distribution of dopants in an ion implantation process, a reactivation state after annealing, and internal deformation in a selective epitaxial growth process of silicon germanium (SiGe) described above using a physical measurement device such as an optical critical dimension (OCD), a critical dimension-scanning electron microscope (CD-SEM), etc. In addition, chemical measurement methods using fluorescence X-rays or mass spectrometry are acceptable in terms of precision but have problems in throughput. In addition, chemical measurement methods are often destructive tests.

As another approach, electrical characteristics inspection includes inspection of a transistor having a metal-oxide-silicon (MOS) structure, which is a basic component. In the transistor inspection, electrical characteristics, such as C-V characteristics, are evaluated by electrically connecting a probe to the transistor. These are direct performance evaluations of semiconductor devices. Transistor inspection, such as laser-assisted device alteration (LADA) or optical beam induced resistance change (OBIRCH), not only confirms defects by introducing light but also may specify a margin for defects or a location of defects within a high-resistance device.

However, the above listed inspections involve contact measurements, and they are inspections which are impossible unless it is a post-semiconductor process in which an interconnection layer or pad is formed. If the evaluation of these electrical characteristics is confirmed in a non-contact manner throughout the entire semiconductor process and expansion of a depletion layer or inversion region formed inside a semiconductor are accurately interpreted, it may be quickly fed back to processes, such as ion implantation and annealing, which is very effective in reducing a development period and manufacturing cycle time. However, measurement technology that satisfies the requirements has not yet been established.

One of the noncontact electrical characteristics measurement technologies that has the potential is inspection using second harmonic generation (SHG) based on nonlinear optical characteristics of a measurement target. Nonlinear optical characteristics appear, for example, as the product of susceptibility and electric field. The susceptibility is obtained from the intensity of the second harmonic. Furthermore, a band structure within a material is obtained from each element of a susceptibility tensor.

Main materials used as semiconductor substrates, such as silicon, have an inversion-symmetric crystal structure, so the second harmonic usually does not occur in a bulk state. However, Bloembergen et al. conducted a theoretical review of the generation of a second harmonic due to symmetry breaking at the interface of materials in Non-Patent Document 1. The generation of a second harmonic reviewed in Non-Patent Document 1 is also quantitatively and experimentally evaluated according to the subsequent development of pulse lasers.

In addition, Guidotti et al. experimentally evaluated the generation of a second harmonic on a silicon surface having an inversion symmetric structure in Non-Patent Document 2. Patent Document 1 proposes a measurement method using the second harmonic for a progress of a process in a semiconductor device. Patent Document 2 proposes a method of evaluating the presence of contaminants on a surface of a semiconductor substrate by observing light having the second harmonic wavelength and light having a sum frequency wavelength generated under illumination of multiple wavelengths.

Patent Document 3 discloses a method of measuring surface roughness at the interface between silicon and an oxide layer. Here, it is described that by rotating a sample, deformation of the sample or the anisotropy of a crystal structure may be detected by measuring azimuthal dependence of the intensity of the second harmonic. In addition, as disclosed in Patent Document 4, dynamic characteristics of charge at an interface may be estimated by analyzing a temporal evolution (i.e., a temporal change) of the intensity of light having the second harmonic wavelength. This is derived from the fact that the intensity of the light having the second harmonic wavelength depends on an interface electric field and that electric charges are generated near the interface upon irradiation of a fundamental wave.

Furthermore, Patent Document 5, which developed the technology of Patent Document 4, proposed a method of saturating temporal evolution before measurement by irradiating ultraviolet light, etc. separately from a fundamental wave, for the purpose of shortening the measurement time.

As shown in these documents, in the measurement of the second harmonic, observation of azimuthal dependence and temporal evolution is considered an effective method of analysis. However, in order to obtain azimuthal dependence, the sample needs to be rotated, so the measurement takes a certain amount of time. Furthermore, because the intensity of the second harmonic evolves over time, the temporal evolution of the intensity of the second harmonic is superimposed on the azimuthal dependence. Although it is possible to saturate temporal evolution in advance by using the technology described in Patent Document 5, it is difficult to observe temporal evolution in that case. Despite the aforementioned problems, the related art technologies do not disclose an unit of separately obtaining temporal evolution and azimuthal dependence.

First, an outline of an embodiment is described. A semiconductor measurement device of the present embodiment may irradiate laser light, such as a pulse laser, to a sample, such as a semiconductor device, to measure contamination on a surface of a semiconductor and measure the amount of dopant or internal deformation inside the semiconductor, for example, in manufacturing semiconductor devices. The semiconductor measurement device may measure nonlinear light, such as the second harmonic generated from a surface of a semiconductor device in fabrication or near an interface of a layered structure in the semiconductor device in fabrication.

In a general optical device, a method of detecting the second harmonic at an interface of a layered structure by irradiating a sample having a layered structure with a fundamental wave with a controlled polarization direction has been used. The intensity of the second harmonic depends on an angle (azimuth) formed between a crystal orientation and the fundamental wave. Therefore, information on the sample may be interpreted based on the azimuthal dependence.

The related method of obtaining the azimuthal dependence of the second harmonic by rotating the sample employs a simple device configuration and inspection method. Moreover, it takes a certain amount of time to rotate the sample. Furthermore, depending on the sample, the intensity of the second harmonic may evolve over time. Therefore, there is a possibility that the intensity of the second harmonic changes during the acquisition of azimuthal dependence in the related method.

Therefore, the semiconductor measurement device of the present embodiment may acquire azimuthal dependence of the second harmonic without rotating the sample. For example, the semiconductor measurement device may collectively measure the intensity distribution of the second harmonic on a pupil plane of an objective lens.

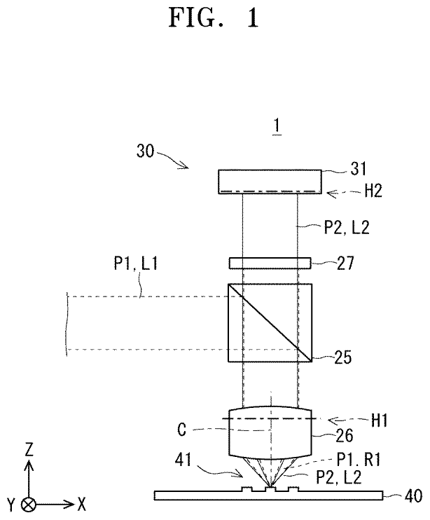

FIG. 1 is a configuration diagram illustrating a semiconductor measurement device 1 according to an embodiment. In FIG. 1 and subsequent drawings, a fundamental wave P1 is shown with the broken line, and a second harmonic P2 (signal light L2) is shown with the solid line.

Referring to FIG. 1, the semiconductor measurement device 1 of the present embodiment may include an objective lens 26, a wavelength filter 27, and a detection unit 30. The semiconductor measurement device 1 may further include an optical member, such as a beam splitter 25. In addition, the semiconductor measurement device 1 may further include a laser light source that generates laser light L1 including the fundamental wave P1.

The objective lens 26 focuses the laser light L1 including the fundamental wave P1 onto a sample surface 41 of a sample 40. The fundamental wave P1 has a first wavelength. The fundamental wave P1 includes pulsed light. The laser light L1 including the fundamental wave P1 is simply referred to as the fundamental wave P1. An optical axis C of the objective lens 26 is disposed to be orthogonal to the sample surface 41 of the sample 40. Accordingly, an optical axis of the fundamental wave P1 is orthogonal to the sample surface 41. Here, being orthogonal means not only strictly 90° but also being orthogonal within a range including an unavoidable error, such as a measurement error.

Here, for convenience of description of the semiconductor measurement device 1, an XYZ orthogonal coordinate axis system is introduced. A direction of the optical axis C of the objective lens 26 is defined as or parallel to a Z-axis direction, and two directions perpendicular to the optical axis C of the objective lens 26 are defined as or parallel to an X-axis direction and a Y-axis direction, respectively.

The sample 40 may receive the fundamental wave P1 and generate the signal light L2. Reflected light R1 reflected from the sample 40 and the signal light L2 may be in a superposition to form a superimposed light. The wavelength filter 27 separates reflected light R1, in which the fundamental wave P1 is reflected from the sample 40, from the signal light L2 which is generated as the fundamental wave P1 is irradiated to the sample 40. In other words, the wavelength filter 27 separates the signal light L2 from the superimposed light of the reflected light R1 and the signal light L2. For example, the wavelength filter 27 may selectively transmit the signal light L2 and block the reflected light R1. The signal light L2 has a second wavelength that is different from the first wavelength. The second wavelength is, for example, half the first wavelength. Here, half means not only ½ strictly, but also half within a range including an unavoidable error, such as a measurement error. The signal light L2 includes pulsed light. The signal light L2 includes a second harmonic P2. The signal light L2 including the second harmonic P2 is simply referred to as the second harmonic P2 throughout the description. The reflected light R1 includes the fundamental wave P1.

The detection unit 30 detects the second harmonic P2 separated from the fundamental wave P1 by the wavelength filter 27. The detection unit 30 may be located to detect the second harmonic P2 generated by the same fundamental wave P1 in two or more different emission directions from the sample 40. In detail, for example, the detection unit 30 may include a detector 31. In that case, the detector 31 may be located at a conjugate position H2 of a pupil plane H1 of the objective lens 26. Thus, the detector 31 may detect the second harmonic P2 generated by the same fundamental wave P1 in two or more different emission directions from the sample 40. The detector 31 may detect the intensity of the second harmonic P2 on the pupil plane H1 of the objective lens 26. For example, the conjugate plane H2 of the pupil plane H1 of the objective lens 26 is a corresponding plane where the signal light L2 is spatially transformed due to the lens's optical properties. In other words, at the conjugate plane H2, the second light L2 may converge or diverge after passing through the pupil plane H1.

The detection unit 30 may include an optical fiber in addition to the detector 31 or together with the detector 31. The detector 31 may be connected to one end of the optical fiber and detect the second harmonic P2 derived from the optical fiber. In this case, the other end of the optical fiber may be located at the conjugate position H2 of the pupil plane H1 of the objective lens 26. Even with this configuration, the detection unit 30 may detect the second harmonic P2 generated by the same fundamental wave P1 in two or more different emission directions from the sample 40.

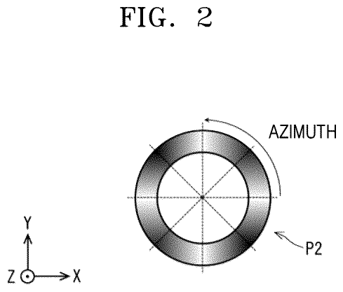

FIG. 2 is a two-dimensional image illustrating components of the second harmonic for each azimuth detected by a detector located at a conjugate position of the pupil plane of the objective lens in the semiconductor measurement device 1 of FIG. 1. In FIG. 2, an intensity distribution of the second harmonic P2 projected on the detector 31 is shown in gray scale. In addition, the fundamental wave P1 irradiated to the sample 40 is shaped by an annular light shaper to be described below.

Referring to FIG. 2, the second harmonic P2 generated from the sample 40 shows an azimuth-dependent distribution within the pupil plane H1 of the objective lens 26. The semiconductor measurement device 1 may collectively acquire information on azimuthal dependence by projecting the signal light L2 having the azimuth distribution onto the detector 31. Hereinbelow, a semiconductor measurement method is described.

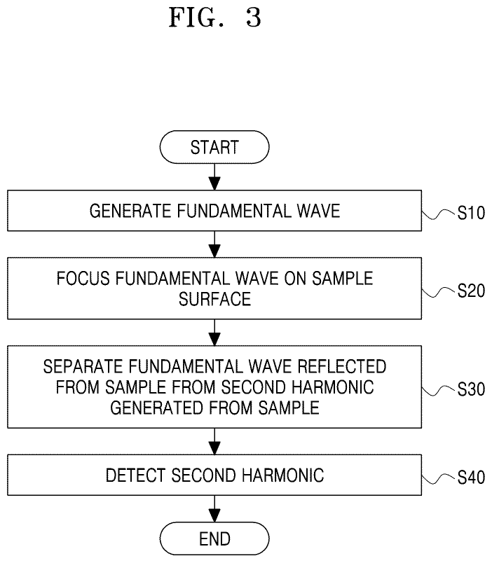

FIG. 3 is a flowchart illustrating a semiconductor measurement method using the semiconductor measurement device 1 of FIG. 1 according to an embodiment.

Referring to FIG. 3, the semiconductor measurement method using the semiconductor measurement device 1 of FIG. 1 according to an embodiment (hereinafter, simply referred to as a ‘semiconductor measurement method’) first generates the fundamental wave P1 having a first wavelength (S10). For example, the fundamental wave P1 having a first wavelength is generated by a laser light source 10.

Next, the fundamental wave P1 is focused on the sample surface 41 (S20). For example, the fundamental wave P1 is focused on the sample surface 41 by the objective lens 26. In operation S20 of focusing the fundamental wave P1 on the sample surface 41, the optical axis C of the objective lens 26 is orthogonal to the sample surface 41.

Thereafter, the fundamental wave P1 reflected from the sample 40 is separated from the second harmonic P2 generated by the sample 40 by the wavelength filter 27 (S30). The second harmonic P2 may have a second wavelength. In the operation (S30) of separating the fundamental wave P1 from the second harmonic P2, the second wavelength may be half of the first wavelength.

Thereafter, the second harmonic P2 separated by the wavelength filter 27 is detected by the detection unit 30 (S40). In operation S40 of detecting the second harmonic P2, the detection unit 30 may be located at the conjugate position H2 to detect the intensity of the second harmonic P2 generated by the same fundamental wave P1 in two or more different emission directions from the sample 40.

In this manner, according to the outline of the present embodiment, the detection unit 30 may be located at the conjugate position H2 to detect the second harmonic P2 generated by the same fundamental wave P1 in two or more different emission directions from the sample 40. Therefore, because the azimuth dependency of the second harmonic P2 is acquired collectively, there is no influence of temporal evolution and the precision of measurement may be improved. In addition, because the azimuthal dependence of the second harmonic P2 may be acquired without rotating the sample 40, measurement throughput may be improved and a measurement device configuration may be simplified. Furthermore, because the optical axis of the objective lens 26 is orthogonal to the sample surface 41, measurement accompanied by movement of a field of view may be performed by moving the sample 40. In addition, temporal evolution may be measured in each direction at a once.

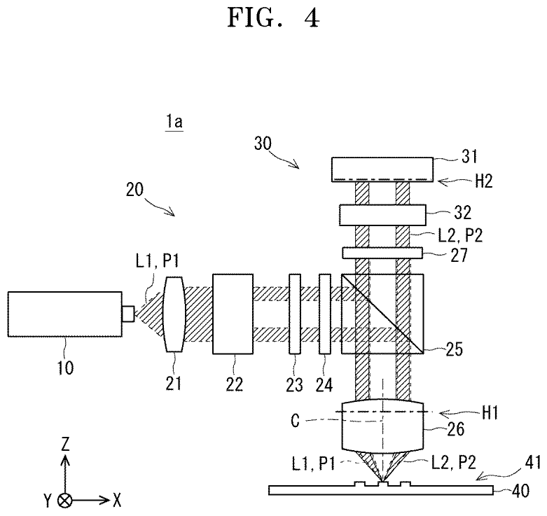

FIG. 4 is a configuration diagram illustrating a semiconductor measurement device 1a according to an embodiment.

Referring to FIG. 4, the semiconductor measurement device 1a may include a laser light source 10, an optical system 20, and a detection unit 30. In addition, the semiconductor measurement device 1a may further include components, such as an annular light shaper, a polarization controller, and a delay generator, compared to the components provided in the semiconductor measurement device 1 of FIG. 1.

The laser light source 10 generates a fundamental wave P1 having a first wavelength. For example, the laser light source 10 may include a pulse laser light source that generates the fundamental wave P1, which is a pulse-type fundamental wave. The pulse width of the fundamental wave P1 may be 1 picosecond or less. The fundamental wave P1 generated by the laser light source 10 is emitted from the laser light source 10 and guided to the optical system 20.

The optical system 20 generates nonlinear light by irradiating the fundamental wave P1 to the sample 40. The nonlinear light includes, for example, a second harmonic P2. The nonlinear light including the second harmonic P2 is referred to as signal light L2. In addition, as described above, the signal light L2 including the second harmonic P2 is simply referred to as the second harmonic P2. The optical system 20 guides the generated second harmonic P2 to the detection unit 30. In addition, the optical system 20 separates the second harmonic P2 from reflected light R1, in which the fundamental wave P1 is reflected from the sample 40 using a wavelength filter 27. Hereinafter, optical members included in the optical system 20 are described in detail.

The optical system 20 may include a collimator 21, an annular light shaper 22, a polarization controller 23, a delay generator 24, a beam splitter 25, an objective lens 26, and the wavelength filter 27. The optical system 20 may further include optical members other than the above optical members, and some of the optical members may be omitted. For example, the delay generator 24 may be omitted. The collimator 21, the annular light shaper 22, the polarization controller 23, the delay generator 24, and the beam splitter 25 may be located between the laser light source 10 and the objective lens 26 at an optical path of the fundamental wave P1.

The collimator 21 converts the fundamental wave P1 output from the laser light source 10 into parallel light. The collimator 21 is, for example, a condensing lens. The fundamental wave P1 which is converted into parallel light using the collimator 21 is incident on the annular light shaper 22.

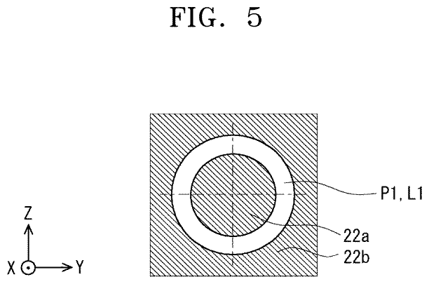

FIG. 5 is a diagram illustrating a cross-section orthogonal to an optical axis of a fundamental wave shaped by an annular light shaper in the semiconductor measurement device 1a of FIG. 4. In FIG. 5, the optical axis of the fundamental wave P1 is in an X-axis direction.

Referring to FIG. 5, the annular light shaper 22 shapes the fundamental wave P1 into an annular shape. The annular light shaper 22 may be an annular aperture having a light blocking portion 22a and an edge portion 22b or may include a plurality of axicon lenses. In some embodiments, the fundamental light wave P1 may be blocked by the light blocking portion 22a and the edge portion 22b, passing through a space between the light blocking portion 22a and the edge portion 22b. The space may have a ring or annular shape. The annular light shaper 22 may adjust an incident angle of the fundamental wave P1 incident on the sample 40 by shaping the fundamental wave P1 into an annular shape. In detail, the incident angle is adjusted to be in a desired range by adjusting inner and outer diameters of the annular fundamental wave P1 in the annular light shaper 22. For example, it is desirable to set the incident angle from about 45° to 60°, in which the intensity of the second harmonic P2 is relatively high. Because an optimal incident angle varies depending on the sample 40, a mechanism may adjust the incident angle of the fundamental wave P1. That is, the annular light shaper 22 may have a mechanism capable of adjusting the outer diameter of the light blocking portion 22a and the inner diameter of the edge portion 22b. The fundamental wave P1 shaped into an annular shape is incident on the polarization controller 23. In some embodiments, the axicon lens may be a conical optical element typically used to transform a laser beam into a ring-shaped or Bessel beam pattern. The axicon lens may adjust the incident angle of light. When light passes through an axicon lens, it refracts and converges towards the axis of the cone. The angle of convergence depends on the cone's apex angle and the wavelength of light. By changing the geometry of the axicon lens, the convergence angle is changed, thereby adjusting the incident angle of the light.

The polarization controller 23 may include, for example, a polarizer. In some embodiments, the polarization controller 23 may be a polarizer. The polarization controller 23 controls a polarization state of the fundamental wave P1. The polarization controller 23 may generate a certain polarization state of the fundamental wave P1 on the pupil plane H1 of the objective lens 26. For example, the fundamental wave P1 passing through the polarization controller 23 may have the certain polarization state at the pupil plane H1 of the objective lens 26. The polarization state includes linear polarization, circular polarization, radial polarization, and azimuthal polarization. The polarization state of the fundamental wave P1 may be linearly polarized or circularly polarized, but as described below, radial polarization or azimuthal polarization is desirable. A particular polarization state may be radial polarization, azimuthal polarization, and a combination of the radial polarization and the azimuthal polarization.

The delay generator 24 is described below. The fundamental wave P1 of which the polarization state is controlled is incident on the beam splitter 25.

The beam splitter 25 reflects part of the incident fundamental wave P1 and allows part of the incident fundamental wave P1 to be transmitted therethrough. The beam splitter 25 may be a dichroic mirror that reflects the fundamental wave P1 and allows the second harmonic P2 to be transmitted therethrough. By using the dichroic mirror, the energy of each of the fundamental wave P1 and the second harmonic P2 may be used efficiently. The fundamental wave P1 reflected from the beam splitter 25 is incident on the objective lens 26.

The objective lens 26 focuses the fundamental wave P1 on the sample surface 41 of the sample 40. The sample surface 41 is, for example, the upper surface of the sample 40. The fundamental wave P1 guided to the objective lens 26 by the beam splitter 25 is focused on the sample 40. The reflected light R1 and the second harmonic P2 of the fundamental wave P1 are emitted from the sample 40 to which the fundamental wave P1 is irradiated.

The fundamental wave P1 reflected from the sample 40 and the second harmonic P2 emitted from the sample 40 pass through the objective lens 26 and are made to be incident on the beam splitter 25. The beam splitter 25 allows the fundamental wave P1 and the second harmonic P2 to be transmitted therethrough. In addition, when the beam splitter 25 is a dichroic mirror, the beam splitter 25 allows the second harmonic P2 to be transmitted therethrough. The fundamental wave P1 and the second harmonic P2 that pass through the beam splitter 25 are incident on the wavelength filter 27.

The wavelength filter 27 separates the signal light L2 from the reflected light R1, in which the fundamental wave P1 is reflected from the sample 40. The signal light L2 may include the second harmonic P2 generated as the sample 40 is irradiated with the fundamental wave P1. In detail, the wavelength filter 27 removes the fundamental wave P1 and guides the second harmonic P2 to the detection unit 30. For example, the wavelength filter 27 may block the reflected light R1 while passing the signal light L2. The wavelength filter 27 is an optical element, such as an optical interference filter, a short pass filter, a band pass filter, or a dichroic mirror (i.e., a dichroic filter), and an optical element capable of separating optical paths by a wavelength may be used. The second harmonic P2 passing through the wavelength filter 27 is incident on the detection unit 30. In some embodiments, the optical interference filter serving as the wavelength filter 27 may operate based on the principle of interference, transmitting a narrow range of wavelengths (e.g., the signal light L2 of the superimposed light) while blocking others (the reflected light R1 of the superimposed light). In some embodiments, the dichroic filter serving as the wavelength filter 27 may separate or combine different wavelengths of light, by reflecting certain wavelengths (e.g., the reflected light R1) while transmitting others (e.g., the signal light L2).

The detection unit 30 may further include a polarization analyzer 32 in addition to the detector 31. The polarization analyzer 32 analyzes a polarization state. In detail, the polarization analyzer 32 extracts a desired polarization state from the second harmonic P2. For example, the polarization analyzer 32 generates an interference pattern reflecting the polarization state of the second harmonic P2 and provides the second harmonic P2 having the interference pattern to the detector 31. The detector 31 may detect the interference pattern of the second harmonic P2. The interference pattern may be the result of the superposition of the second harmonics P2 emitted in two or more different emission directions from the sample, creating alternating regions of constructive and destructive interference. When the second harmonic P2 with a specific polarization interacts with the sample surface 41 of the sample 40, it may generate an interference pattern that exhibits polarization-dependent behavior. This pattern can reveal information about the polarization state of the second harmonic P2 and the properties of the sample surface 41 it interacts with.

The detector 31 may have a plurality of photosensitive surfaces. The number of photosensitive surfaces may be equal to the number of time differences generated by the delay generator 24 to be described below. Each photosensitive surface receives the second harmonic P2 at every time difference. The detector 31 of the detection unit 30 may detect the second harmonic P2 generated by the fundamental wave P1 having a time difference at every time difference in a dividing manner.

As a method of realizing the polarization analyzer 32, only a linear polarizer may be used, or an elliptical polarization analysis method of arranging a Nomarski prism and a linear polarizer may be applied. This is an application of the ellipsometry method disclosed in Patent Document 6. The second harmonic P2 in the desired polarization state is detected by the detection unit 30. Here, the detection unit 30 has a configuration capable of acquiring azimuthal dependence of the intensity of the second harmonic P2 at sufficiently high speed. Two certain examples are given below.

One example is as follows: the detection unit 30 may include the detector 31 having a plurality of photosensitive surfaces (i.e., a plurality of photo sensors), such as a complementary metal-oxide semiconductor (CMOS) sensor and a split photo multiplier tube (PMT). For example, the photo sensors may detect light and converts it into an electrical signal. In this case, the detection unit 30 has an optical configuration in which the intensity distribution of the second harmonic P2 on the pupil plane H1 of the objective lens 26 is projected onto each photosensitive surface. In some embodiments, the photosensitive surface of the detector 31 may be located at the conjugate position H2 of the pupil plane H1 to receive the signal light L2 and measure the intensity distribution of the second harmonic P2. In some embodiments, a cross-section of an optical fiber may be located at the conjugate position H2 of the pupil plane H1 to receive the signal light L2 and the received signal light L2 may travel to the detector 31 through the optical fiber connected to the detector 31.

The other example is as follows: it is a method of separating temporally rather than spatially. For example, the detection unit 30 may detect the second harmonic P2 with the detector 31 having high time resolution, such as a streak camera, by applying an optical path delay to each position of the pupil plane H1. Thus, the detection unit 30 may detect the intensity distribution of the pupil plane H1 by dividing the intensity distribution by time.

A polarization state of the fundamental wave P1 on the sample 40 is considered. In a case in which the fundamental wave P1 is controlled to have linear polarization by a polarizer, an angle between an incident plane and a polarization direction is different for light at each azimuth angle. This angle is hereafter referred to as a polarization angle. The second harmonic P2 also shows dependence on the polarization angle. For this reason, in order to facilitate data analysis, it is preferable that the polarization angle in each direction is the same. Therefore, the polarization controller 23 may adjust the fundamental wave P1 to have radial polarization or azimuthal polarization. The fundamental wave P1, including radial polarization and azimuthal polarization, has the same polarization angle in any orientation. Therefore, analysis of the second harmonic P2 may be facilitated.

The optical system 20 may further include the delay generator 24. For example, the fundamental wave P1 emitted from the polarization controller 23 is incident on the delay generator 24. The fundamental wave P1 emitted from the delay generator 24 is incident on the beam splitter 25.

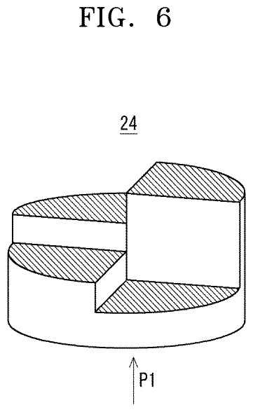

FIG. 6 is a perspective view illustrating a delay generator having a distribution in the thickness of the fundamental wave in the optical axis direction in the semiconductor measurement device 1a of FIG. 4.

Referring to FIG. 6, the delay generator 24 may include a transmission member having a thickness distribution in the optical axis direction of the fundamental wave P1. In some embodiments, the delay generator 24 may be the transmission member with the thickness distribution in the optical axis direction of the fundamental wave P1. Having a distribution in thickness refers to having two or more different thicknesses depending on portions of the delay generator 24. In the delay generator 24, the thickness may change continuously or may discontinuously change stepwise. By allowing the fundamental wave P1 to be transmitted through the transmission member having a distribution of thickness, the timing of irradiating the sample 40 may be delayed. In this manner, the delay generator 24 generates a time difference according to the difference in the optical path length of the fundamental wave P1 transmitted through the transmission member. The delay generator 24 in the drawing is divided into four parts having different optical path delays, but the number of divisions may be arbitrarily determined. Also, in this case, the detector 31 may have four photosensitive surfaces respectively corresponding to the four portions of the delay generator 24. In some embodiments, the detector 31 and the delay generator 24 may be arranged such that each of the four photosensitive surface of the detector 31 receives the delayed fundamental wave P1 of a corresponding portion of the four portions of the delay generator 24.

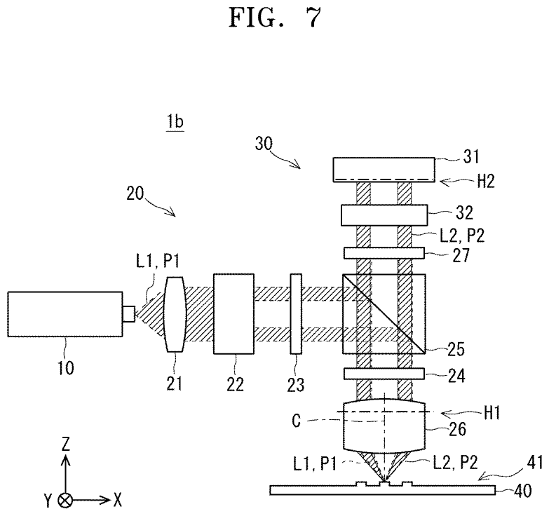

FIG. 7 is a configuration diagram illustrating a semiconductor measurement device 1b according to an embodiment.

Referring to FIG. 7, in the optical system 20 of the semiconductor measurement device 1b, the delay generator 24 may be located between the beam splitter 25 and the objective lens 26, instead of between the annular light shaper 22 and the beam splitter 25.

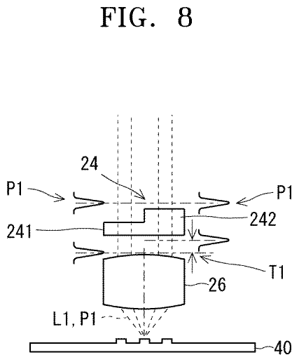

FIG. 8 is a diagram illustrating the time difference between fundamental waves generated by the delay generator 24 in the semiconductor measurement device 1b of FIG. 7.

Referring to FIG. 8, the delay generator 24 may include a first portion 241 and a second portion 242 having different thicknesses in the optical axis direction. The first portion 241 has a smaller thickness in the optical axis direction than the second portion 242. Accordingly, the fundamental wave P1 passing through the first portion 241 generates a time difference T1 at the timing of irradiating the sample 40 compared to the fundamental wave P1 passing through the second portion 242. For example, the fundamental wave P1 passing through the first portion 241 may pass through the delay generator 24 earlier than the fundamental wave P1 passing through the second portion 242 by the time difference T1. In this manner, by transmitting the fundamental wave P1 through a transmission member having a thickness distribution in the optical axis direction, the timing of irradiating the sample 40 may be delayed.

There are two tasks that the delay generator 24 may solve. The first task is the generation of a non-coaxial second harmonic P2. When the annular fundamental wave P1 is focused on the sample surface 41, optical electric fields on the sample surface 41 may interfere with each other and concentrate in one direction. In that case, even if the second harmonic P2 is detected for each azimuth, the intensity is constant, and thus, a desired intensity distribution cannot be obtained. The second task is signal strength. Generally, the intensity of the second harmonic P2 is much smaller than that of the fundamental wave P1. For this reason, dispersing light on the pupil plane 26a is undesirable from the viewpoint of signal to noise (S/N). In terms of a damage threshold of the sample 40, there is a limit to the intensity of the fundamental wave P1 that may be irradiated with one pulse. The damage threshold may refer to a maximum intensity of the fundamental wave P1 without causing damage on a sample on which the fundamental wave P1 is irradiated.

In order to solve the above problem, the fundamental wave P1 before being irradiated to the sample 40 is allowed to pass through the delay generator 24. As a result, it is possible to generate a time difference for each azimuth with respect to the timing at which the fundamental wave P1 is irradiated to the sample 40. The delay generator 24 may have a thickness distribution in the azimuthal direction as shown in FIG. 6, for example, and may include a material that is transparent for the wavelength of the fundamental wave P1. As a result, the intensity in each azimuth component, rather than the total intensity of all fundamental waves P1, need not exceed the damage threshold, and the limitation on the intensity of the fundamental wave P1 is alleviated.

An irradiation timing that has to be delayed for each azimuth angle is about a pulse width to a repetition period of pulse laser (e.g., 1 picosecond to 100 nanoseconds) and is short enough for the exposure time (>milliseconds) of the detector 31 and temporal evolution (>a few seconds) of the intensity of the second harmonic P2. For this reason, collective acquisition is not damaged due to the discrepancy. In addition, when only the first task needs to be achieved, interference on the sample 40 may be suppressed as long as the S/N is sufficient. For this reason, the discrepancy in irradiation timing may be about the pulse width. Thus, the delay generator 14 generates a time difference for a portion of the fundamental wave P1 to reach the sample 40 with respect to another portion. For example, the delay generator 14 generates a time difference between when one part of the fundamental wave P1 reaches the sample 400 and when another part reaches it. The detector 31 may be located to detect the second harmonic P2 generated by the same fundamental wave P1 separately at each time in two or more different emission directions from the sample 40.

Furthermore, the detector 31 may have a photosensitive surface corresponding to the division of the delay generator 24. In this case, one detector 31 does not necessarily have to have a plurality of photosensitive surfaces, and a plurality of detectors 31 may also be arranged. In some embodiments, a photodetector such as a photodiode and a PMT may serve as the detector 31. Furthermore, by arranging a lens array in front of the detector 31, the fundamental wave P1 may be focused for each division of the delay generator 24. Accordingly, the amount of detection signal may increase. Here, the number of divisions is set arbitrarily from a desired period of azimuthal dependence or S/N ratio. In addition, the light blocking portion 22a and the edge portion 22b of the annular light shaper 22 may be designed according to the number of divisions. In detail, a structure may be used in which holes are arranged in an annular shape equal to the number of divisions.

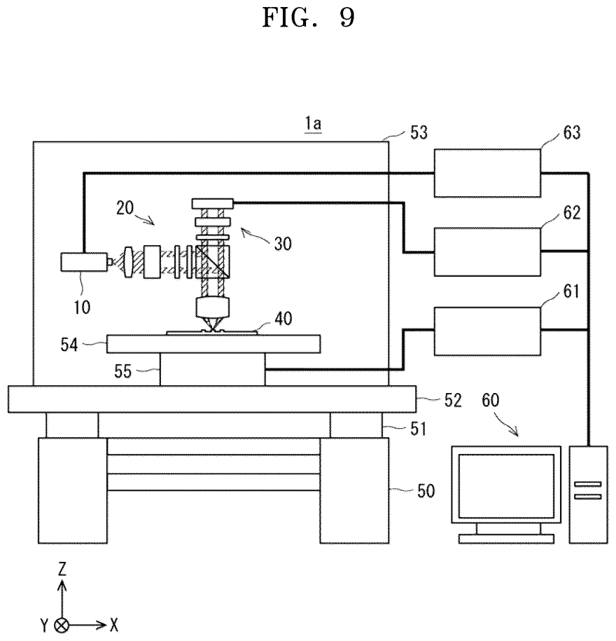

FIG. 9 is a configuration diagram illustrating a semiconductor measurement device 1a according to an embodiment.

Referring to FIG. 9, the semiconductor measurement device 1a may be located on an optical table 52 supported by a stand 50. An isolator 51 may be located between the stand 50 and the optical table 52. The isolator 51 removes vibrations from the floor surface on which the stand 50 is located. Any one of the laser light source 10, the optical system 20, and the detection unit 30 may be fixed to a frame 53 installed on the optical table 52. The sample 40 is held in a holder 54 and located on a stage 55. The stage 55 may move in the X-axis, Y-axis, and Z-axis directions and may rotate in at least one of the X-axis, Y-axis, and Z-axis directions as a rotation axis.

The semiconductor measurement device 1a may further include a control device 60, a stage controller 61, a signal processing unit 62, and a laser light source controller 63. The control device 60 controls the operations of the stage controller 61, the signal processing unit 62, and the laser light source controller 63. The control device 60 may include, for example, an information processing device, such as a personal computer (PC) and a server.

The stage controller 61 controls a position of the stage 55. For example, the stage controller 61 changes the position of the stage 55 by moving or rotating the stage 55. Thus, the stage controller 61 controls the position of the sample 40 irradiated by the fundamental wave P1.

The signal processing unit 62 converts the intensity and distribution of the second harmonic P2 detected by the detection unit 30 into an electrical signal. Also, the signal processing unit 62 may process the resultant electrical signal and transmit the processed electrical signal to the control device 60.

The laser light source controller 63 controls the laser light source 10 to generate the fundamental wave P1. The laser light source controller 63 controls at least one of the intensity, wavelength, and pulse width of the generated fundamental wave P1. Hereinbelow, a semiconductor measurement method is described.

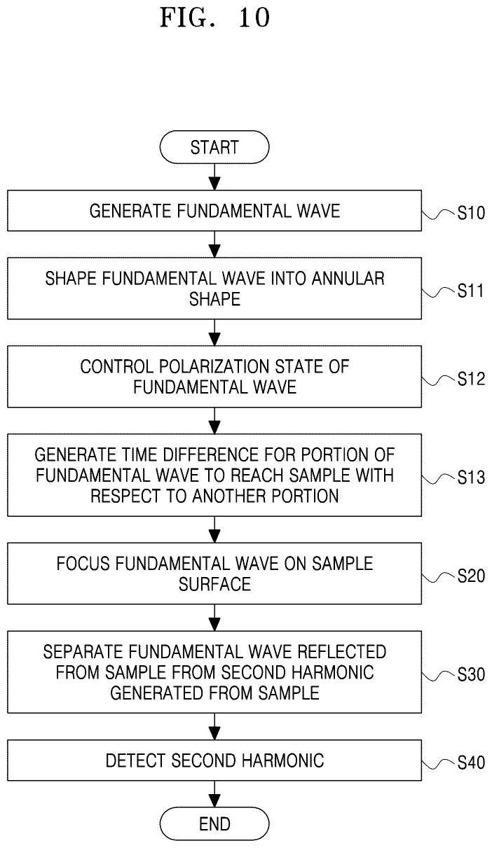

FIG. 10 is a flowchart illustrating a semiconductor measurement method using the semiconductor measurement device 1a of FIG. 9.

Referring to FIG. 10, the semiconductor measurement method of the present embodiment may further include at least one of an operation (S11) of shaping the fundamental wave P1 into a ring shape by the annular light shaper 22, an operation (S12) of controlling a polarization state of the fundamental wave P1 by the polarization controller 23, and an operation (S13) of generating the time difference for a portion of the fundamental wave P1 to reach the sample 40 with respect to another portion by the delay generator 24, compared to the semiconductor measurement method in the outline of the embodiment described above.

First, the fundamental wave P1 is generated (S10). For example, the control device 60 may generate the fundamental wave P1 having a first wavelength by the laser light source 10 by controlling the laser light source controller 63. In the operation (S10) of generating the fundamental wave P1, the laser light source 10 may include a pulse laser light source that generates a pulse-type fundamental wave P1, and the pulse width of the fundamental wave P1 may be 1 picosecond or less.

Next, the fundamental wave P1 is shaped into a ring shape by the annular light shaper 22 (S11).

Thereafter, a polarization state of the fundamental wave P1 is controlled by the polarization controller 23 (S12). For example, the polarization controller 23 may generate a certain polarization state on the pupil plane H1 of the objective lens 26. A certain polarization distribution may include any one of radial polarization, azimuthal polarization, and a combination of radial polarization and azimuthal polarization. In this case, in the operation (S40) of detecting the second harmonic P2, the polarization analyzer 32 may generate an interference pattern reflecting a polarization state of the second harmonic P2 on the detector 31.

Next, the delay generator 24 generates a time difference for a portion of the fundamental wave P1 to reach the sample 40 with respect to another portion of the fundamental wave P1 (S13). For example, the delay generator 24 may include a transmission member having a thickness distribution in the optical axis direction of the fundamental wave P1 and may generate a time difference according to a difference in an optical path length of the fundamental wave P1 passing through the transmission member. In this case, the detection unit 30 may include a detector 31 that detects the second harmonic P2 generated by the fundamental wave P1 having a time difference at every time difference in a dividing manner. For example, the detection unit 30 may include the detector 31 having a plurality of photosensitive surfaces. The number of photosensitive surfaces is equal to the number of time differences generated by the delay generator 24, and each photosensitive surface receives the second harmonic P2 to correspond to the second harmonic P2 of each time difference.

Next, the fundamental wave P1 is focused on the sample surface 41 (S20). For example, the control device 60 focuses the fundamental wave P1 on the sample surface 41 through the objective lens 26 by controlling the stage controller 61.

Thereafter, the fundamental wave P1 reflected from the sample 40 is separated from the second harmonic P2 generated from the sample 40 (S30). For example, the control device 60 separates the fundamental wave P1 from the second harmonic P2 by the wavelength filter 27 by controlling the optical system 20.

Next, the second harmonic P2 is detected (S40). In the operation (S40) of detecting the second harmonic P2, the detection unit 30 may include the detector 31 detecting the intensity of the second harmonic P2 in the pupil plane H1 of the objective lens 26. The detector 31 may be located at the conjugate position H2 of the pupil plane H1 of the objective lens 26 and may have a plurality of photosensitive surfaces.

Hereinafter, a reference example and tasks in the reference example are described, before the effects of the present embodiment are described. Thereafter, the effects of the present embodiment are described compared with the reference example. In addition, a semiconductor measurement device related to the reference example may also be included in the technical idea of the present embodiment.

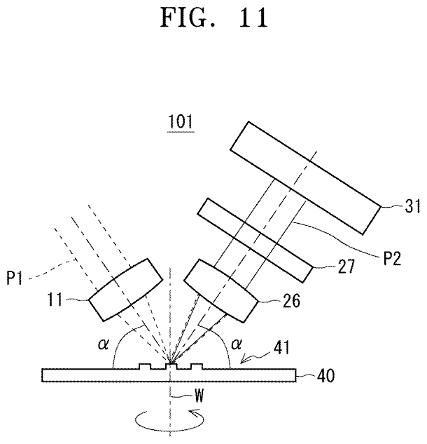

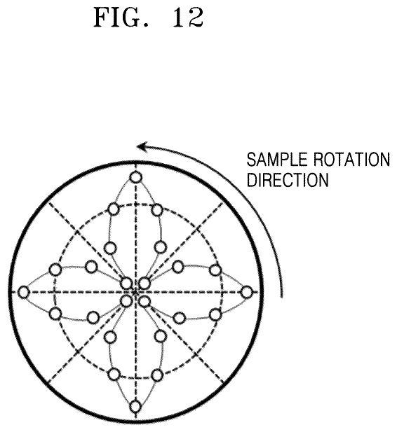

FIG. 11 is a configuration diagram showing a semiconductor measurement device 101 according to a reference example, and FIG. 12 is a diagram showing azimuthal dependence detected by a detector in the semiconductor measurement device 101 of FIG. 11.

Referring to FIGS. 11 and 12, the semiconductor measurement device 101 according to the reference example focuses the fundamental wave P1 on the sample 40 at an incident angle α inclined with respect to the sample surface 41 of the sample 40. Also, the semiconductor measurement device 101 detects the second harmonic P2 generated from the sample 40 at a reflection angle α inclined with respect to the sample surface 41. The semiconductor measurement device 101 repeats detection of the second harmonic P2 by rotating the sample 40 about the rotation axis W orthogonal to the sample surface 41. Thus, azimuthal dependence as shown in FIG. 12 is obtained. The azimuthal dependence is obtained by plotting the intensity of the second harmonic P2 at each azimuth in a radial direction.

In the semiconductor measurement device 101 of the reference example, the sample 40 needs to be rotated around the rotation axis W in order to obtain azimuthal dependence, so measurement takes a certain amount of time. Furthermore, the intensity of the second harmonic P2 changes over time. For this reason, the temporal evolution of the intensity of the second harmonic P2 is superimposed on the azimuthal dependence.

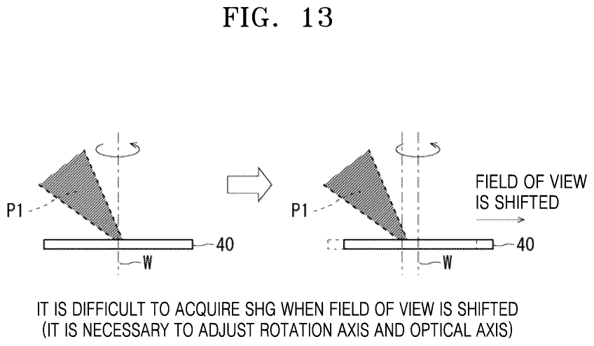

FIG. 13 is a diagram showing a configuration of the semiconductor measurement device 101 of FIG. 11 when the field of view is shifted.

Referring to FIG. 13, generally, when an XY stage is moved to perform a field of view movement, the rotation axis W moves together. In other words, the optical axis and the rotation axis W are inevitably misaligned. In order to adjust this, for example, a mechanism that moves the necessary rotation axis W independently of the movement of the field of view is required, such as mounting the XY stage on the sample 40 side rather than a rotation stage, which significantly limits a device configuration.

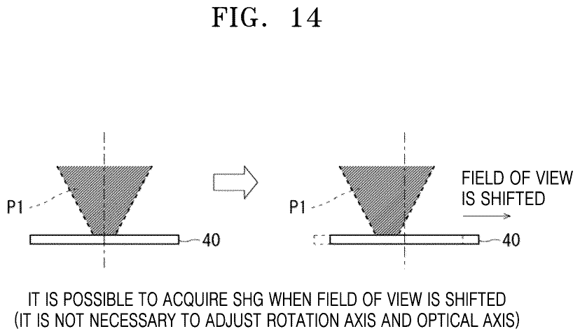

FIG. 14 is a diagram illustrating a configuration of the semiconductor measurement device 10a of FIG. 9 when the field of view is shifted.

Referring to FIG. 14, the semiconductor measurement device 1a of the present embodiment may acquire the azimuthal dependence collectively without rotating the sample 40. In addition, because a rotation mechanism for the sample 40 is not required, the configuration of the device may be simplified and the device may be reduced in price. Furthermore, ease of alignment and movement of the field of view may be realized. In addition, when the field of view is shifted, adjustment with the optical axis is not required because the rotation axis W does not exist. For this reason, throughput of the measurement may be significantly improved.

In addition, the semiconductor measurement device 1a of the present embodiment may obtain the azimuthal dependence of the second harmonic P2 separately from the temporal evolution. As a result, the precision of the azimuthal dependence of the second harmonic P2 may be improved.

The semiconductor measurement device 1a of the present embodiment may measure the temporal development of the intensity of the second harmonic P2 in all desired directions by continuously irradiating the fundamental wave P1. For example, in a plane perpendicular to the optical axis of the second harmonic P2, the intensity of a second harmonic P2-1 at a position of =0° from a predetermined radial direction and the intensity of a second harmonic P2-2 at a position of ϕ=45° from a predetermined radial direction evolve over time. Normally, when measuring the temporal evolution of the intensity of the second harmonic P2, it is limited to a position in one direction. For this reason, there is a possibility that information may be lost in the case that an angle is not at a level at which a desired signal may be obtained. Because the semiconductor measurement device 1 of the present embodiment may measure the temporal evolution of the second harmonic P2 at ϕ=0° to 360°, information is less likely to be lost and the temporal evolution is obtained.

In addition, although it varies depending on the sample 40, changes in temporal evolution over several hundred seconds are obtained. Therefore, in the case of multi-directional detection, the sample 40 is added and measured repeatedly. For this reason, a time of several thousand seconds or more is required. However, because the semiconductor measurement device 1 of the present embodiment may acquire temporal evolution in all directions at once, it may be compressed to about 100 seconds, the same number as acquisition in one direction.

In addition, the semiconductor measurement device 1 of the present embodiment may make it unnecessary to adjust the rotation axis and optical axis of the sample 40, as described above. In addition to the advantage of not requiring an adjustment mechanism and the advantage of improving the precision of azimuthal dependence, this has the advantage of making it very easy to move the field of view of the sample 40 as the stage moves. Considering that the rotation stage is generally installed closer to the sample 40 than the XY stage, it is conceivable that the rotation axis and optical axis are misaligned as the stage moves. Therefore, it is necessary to introduce eucentric control or to mount the XY stage on the sample 40 side rather than the rotation stage. This is a major constraint on device configuration. The semiconductor measurement device 1 of the present embodiment is free from the constraint and may freely move the sample 40 in the field of view.

Hereinbelow, a semiconductor measurement device according to another embodiment is described. In the semiconductor measurement device of another embodiment, a configuration and location of a delay generator may be different, compared to the semiconductor measurement device 1a of the embodiment described above.

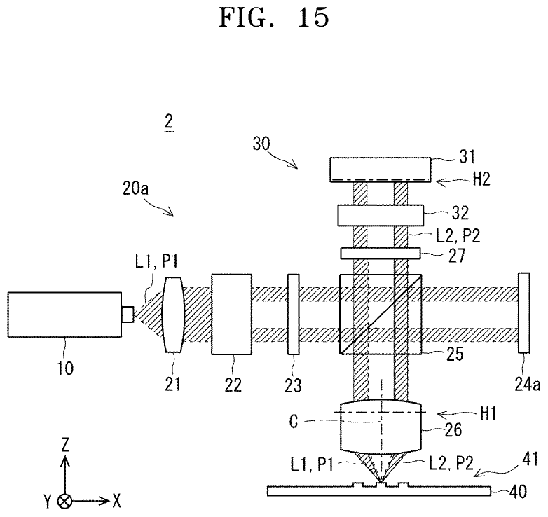

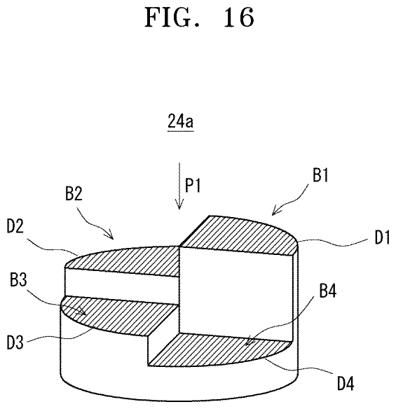

FIG. 15 is a configuration diagram illustrating a semiconductor measurement device 2 according to an embodiment, and FIG. 16 is a perspective view illustrating a delay generator in the semiconductor measurement device 2 of FIG. 15.

Referring to FIGS. 15 and 16, in the semiconductor measurement device 2 of the present embodiment, an optical system 20a may have a delay generator 24a, instead of the delay generator 24.

Unlike the delay generator 24 in the embodiment described above, the delay generator 24a reflects the fundamental wave P1, rather than allowing the fundamental wave P1 to be transmitted therethrough, thereby causing a discrepancy in the timing of irradiation to the sample 40. For example, the delay generator 24a may have a reflective member divided into a plurality of portions B1 to B4 having different positions D1 to D4 of reflection surfaces in the optical axis direction of the fundamental wave P1. The delay generator 24a is disposed to be adjacent to the beam splitter 25 in a +X axis direction in the optical system 20a. Accordingly, the beam splitter 25 is located between the polarization controller 23 and the delay generator 24a.

The fundamental wave P1 emitted from the polarization controller 23 is incident on the beam splitter 25. The beam splitter 25 allows a portion of the fundamental wave P1 incident in a −X-axis direction to be transmitted therethrough. The fundamental wave P1 passing through the beam splitter 25 is reflected from the delay generator 24a. The fundamental wave P1 reflected from the delay generator 24a is incident on the beam splitter 25 in the +X-axis direction. The beam splitter 25 reflects a portion of the fundamental wave P1 incident in the +X-axis direction so that the portion of the fundamental wave P1 is incident on the objective lens 26. In addition, the fundamental wave P1 incident on the beam splitter 25 in the −X-axis direction and reflected from the beam splitter 25 is separated by the wavelength filter 27. Other optical paths are the same as those in the embodiment described above.

In this manner, the delay generator 24a includes a reflective member having a distribution in height in the optical axis direction of the fundamental wave P1 and generates a time difference according to the difference in the optical path length of the fundamental wave P1 reflected from the reflective member. In addition, the delay generator 24a may be any unit, such as a deformable mirror, whereby a portion of light reflected from the delay generator has a different optical path length compared to another portion. In a semiconductor measurement method, in the operation (S13) of generating a time difference in which a portion of the fundamental wave P1 described above reaches the sample 40 with respect to another portion, the delay generator 24a generates a time difference according to the difference in the optical path length of the fundamental wave P1 reflected from the reflective member.

The delay generator 24a may require a reflective member having a high reflectivity for the fundamental wave P1. Because the delay generator 24a is free from passage of a refractive index medium having a different thickness like the delay generator 24, device error factors, such as pulse width changes depending on a divided wavefront, are reduced. Other configurations and effects in the present embodiment are included in the descriptions of the embodiment described above.

Hereinbelow, a semiconductor measurement device according to another embodiment is described. The semiconductor measurement device of another embodiment may differ from the semiconductor measurement device 1a of the first embodiment described above in that a dichroic mirror is used in the wavelength filter 27.

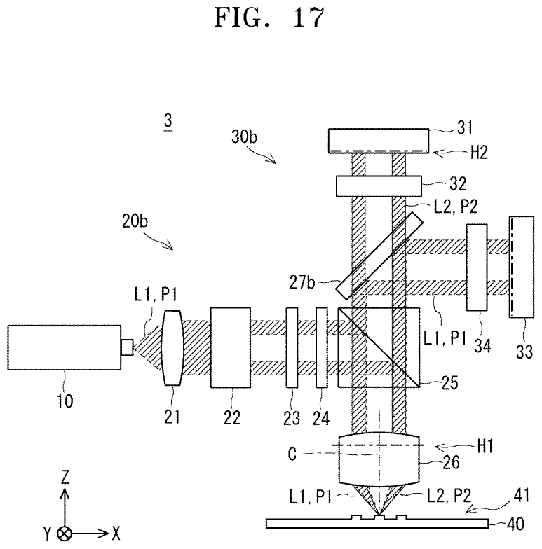

FIG. 17 is a configuration diagram illustrating a semiconductor measurement device 3 according to an embodiment.

Referring to FIG. 17, in the semiconductor measurement device 3 of the present embodiment, an optical system 20b may use a dichroic mirror in a wavelength filter 27b. The detection unit 30b may further include a detector 33 (i.e., a second detector) and a polarization analyzer 34 (i.e., a second polarization analyzer) in addition to the detector 31 (i.e., a first detector) and the polarization analyzer 32 (i.e., a first polarization analyzer). The detector 31 and the polarization analyzer 32 detect and analyze the second harmonic P2, respectively, as in the semiconductor measurement devices 1a and 2 of the first and second embodiments. The detector 33 and the polarization analyzer 34 detect and analyze the fundamental wave P1 separated from the second harmonic P2 by a dichroic mirror, respectively. In detail, the detector 33 detects the intensity of the fundamental wave P1. The polarization analyzer 34 generates an interference pattern reflecting a polarization state of the fundamental wave P1 and provides the interference pattern of the fundamental wave P1 to the detector 33.

The fundamental wave P1 and the second harmonic P2 passing through the beam splitter 25 are separated by the wavelength filter 27b. The wavelength filter 27b including a dichroic mirror reflects, for example, the fundamental wave P1 and allows the second harmonic P2 to be transmitted therethrough. In addition, in an arrangement in which the detector 31 and the polarization analyzer 32 detect and analyze the fundamental wave P1 and the detector 33 and the polarization analyzer 34 detect and analyze the second harmonic P2, the wavelength filter 27b may reflect the second harmonic P2 and allow the fundamental wave P1 to be transmitted therethrough. Other optical paths are the same as those in the first embodiment.

In the semiconductor measurement method, in the operation (S30) of separating the fundamental wave P1 from the second harmonic P2, the wavelength filter 27b may include a dichroic mirror. Also, in operation S40 of detecting the second harmonic P2, the fundamental wave P1 separated from the second harmonic P2 by the dichroic mirror is detected.

According to the present embodiment, because a dichroic mirror is used in the wavelength filter 27b, the fundamental wave P1 separated from the second harmonic P2 may be detected by another detector 33. A detected result may be used to correct the intensity distribution of the second harmonic P2. In addition, the reflected light R1 from the sample 40 may be used for elliptical polarization analysis by the polarization analyzer 34 that detects the fundamental wave P1. Other components and effects in the present embodiment are included in the descriptions of the first and second embodiments described above.

Hereinbelow, a semiconductor measurement device according to another embodiment is described. The semiconductor measurement device of the present embodiment may use a light splitting unit that performs amplitude splitting instead of the annular light shaper 22 and the delay generator 24, compared with the semiconductor measurement device 1a of the first embodiment described above.

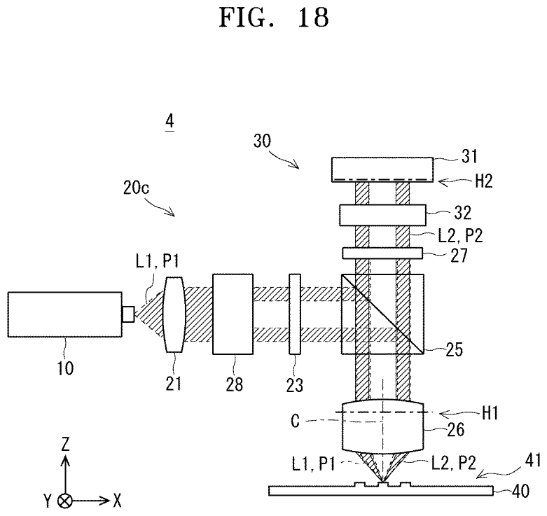

FIG. 18 is a configuration diagram illustrating a semiconductor measurement device 4 according to an embodiment.

Referring to FIG. 18, in the semiconductor measurement device 4 of the present embodiment, an optical system 20c may include a light splitting unit 28, instead of the annular light shaper 22 and the delay generator 24. The light splitting unit 28 is located between the laser light source 10 and the objective lens 26 at the optical path of the fundamental wave P1. The light splitting unit 28 splits the fundamental wave P1 into two or more optical paths and adjusts optical path lengths of the split optical paths. Hereinbelow, examples are described.

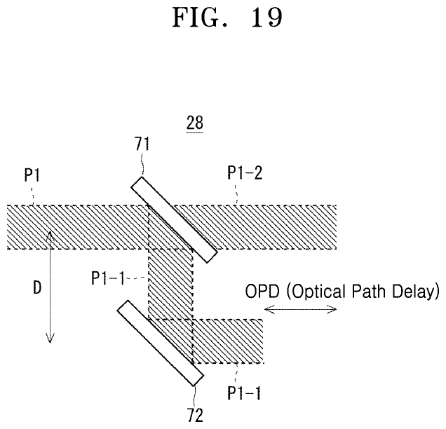

FIG. 19 is a configuration diagram illustrating the light splitting unit 28 in the semiconductor measurement device 4 of FIG. 18.

Referring to FIG. 19, the light splitting unit 28 may include a beam splitter 71 and a mirror 72. In FIG. 19, the light splitting unit 28 may include one beam splitter 71 and one mirror 72. However, the light splitting unit 28 may also include a plurality of beam splitters 71 and a plurality of mirrors 72. The beam splitter 71 may split the fundamental wave P1 into equal amplitude parts. The mirror 72 reflects the fundamental wave P1. For example, the fundamental wave P1 may be split into two parts P1-1 and P1-2 which have the equal amplitude or intensity.

A parallel light including the fundamental wave P1 emitted from the collimator 21 is split by the beam splitter 71. The beam splitter 71 allows a portion of the fundamental wave P1 to be transmitted therethrough and reflects another portion of the fundamental wave P1. A fundamental wave P1-1 reflected from the beam splitter 71 is reflected again by the mirror 72. As a result, the fundamental wave P1-1 reflected by the mirror 72 and a fundamental wave P1-2 transmitted through the beam splitter 71 are made to be parallel.

Here, an optical path delay (OPD) between the fundamental wave P1-1 and the reflected light of the fundamental wave P1-2 may be controlled by a distance D between the beam splitter 71 and the mirror 72 or a thickness of the beam splitter 71. In this manner, the split fundamental wave P1 replicates parallel light. Due to this, unevenness in a directional distribution of light intensity may be suppressed or may be reduced. Furthermore, by installing the light splitting units 28 in multiple stages, the number of splits may be doubled each time. The final number of splits is determined by a desired period of azimuthal dependence or the S/N ratio.

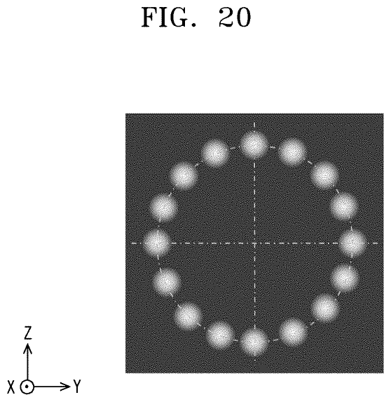

FIG. 20 is a diagram illustrating an intensity distribution at a position of a pupil plane of the fundamental wave split by the light splitting unit in the semiconductor measurement device 4 of FIG. 18.

Referring to FIG. 20, the light splitting unit 28 splits the fundamental wave P1 emitted from the collimator 21 into a plurality of beams. However, in order to unify an incident angle on the sample 40, the beams divided by any number of splits may be arranged in an annular shape. The semiconductor measurement method may further include splitting the fundamental wave P1 into two or more optical paths by the light splitting unit 28 and adjusting optical path lengths of the split optical paths.

According to the present embodiment, the semiconductor measurement device 4 may adjust the optical path lengths of the optical paths split by the light splitting unit 28, so that a time difference may occur depending on a difference in optical path length of the fundamental wave P1, even without the delay generator 24. In addition, the semiconductor measurement device 4 may shape the fundamental wave P1 into a ring shape even without the annular light shaper 22. Other components and effects in the present embodiment are included in the descriptions of the first to third embodiments described above.

Hereinbelow, a semiconductor measurement device according to an embodiment is described. The semiconductor measurement device of the present embodiment may not use the delay generator 24 compared to the semiconductor measurement device 1a of the first embodiment described above.

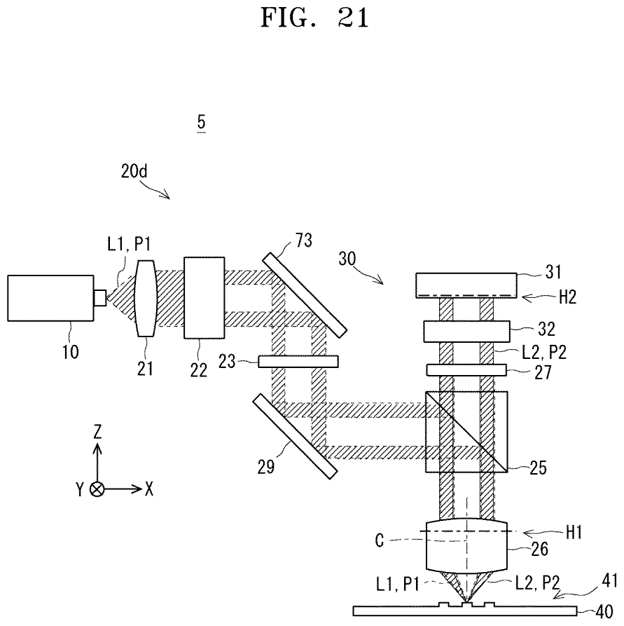

FIG. 21 is a configuration diagram illustrating a semiconductor measurement device 5 according to an embodiment.

Referring to FIG. 21, in the semiconductor measurement device 5 of the present embodiment, an optical system 20d may not have the delay generator 24. When the delay generator 24 is not used, the fundamental wave P1 collected by the objective lens 26 may interfere with the sample surface 41.

When the fundamental wave P1 is incident from one direction as in the reference example described above, an optical electric field on the sample surface 41 has a component in a direction parallel to the sample surface 41. The optical electric field on the sample surface 41 cannot be directed only in a direction perpendicular to the sample surface 41.

Meanwhile, in the case of not having the delay generator 24 like the semiconductor measurement device 5 of the present embodiment, when radially polarized light is incident on the sample surface 41 from an omnidirectional angle, the optical electric field of the sample surface 41 is concentrated only in the direction perpendicular to the sample surface 41 due to interference. Therefore, in order not to generate an optical electric field in a direction perpendicular to the sample surface 41, azimuthally polarized light is incident on the sample surface 41 from an omnidirectional angle. Second-order nonlinear optical constants take the form of tensors. Due to this, when multiple electric field directions exist on the sample surface 41, complex behavior is exhibited. Therefore, by concentrating the electric field direction in one direction, the terms of the tensor involved may be reduced and the analysis of the second harmonic P2 may be facilitated.

As described above, the polarization direction of the fundamental wave P1 on the sample surface 41 is a very important factor in detecting the second harmonic P2. To control this polarization direction, not only the polarization controller 23, such as a polarizer, but also a spatial phase modulator 29 may be used. The spatial phase modulator 29 is located between the laser light source 10 and the objective lens 26 at the optical path of the fundamental wave P1. In detail, the fundamental wave P1 emitted from the annular light shaper 22 is reflected by the mirror 73 and then converted into polarized light by the polarization controller 23. The fundamental wave P1 converted into polarized light by the polarization controller 23 is incident on the spatial phase modulator 29. The spatial phase modulator 29 adjusts a spatial distribution of the fundamental wave P1, such as a polarization state of the fundamental wave P1. The fundamental wave P1 emitted from the spatial phase modulator 29 is incident on the beam splitter 25. The semiconductor measurement method may further include controlling the polarization state of the fundamental wave P1 by the spatial phase modulator 29.

According to an embodiment, the semiconductor measurement device 5 may perform polarization control with a higher degree of freedom by using the spatial phase modulator 29. Other components and effects in the present embodiment are included in the descriptions of the first to fourth embodiments described above.

The present disclosure is not limited to the above embodiments and appropriate changes may be made without departing from the spirit. For example, the components of the embodiments may be combined with each other. In addition, the following semiconductor measurement method may also be included in the scope of the technical idea of the embodiments.

The technical idea of the present disclosure provides a semiconductor measurement method using a semiconductor measurement device for measuring nonlinear light generated from a sample, wherein the semiconductor measurement device includes: a laser light source configured to generate a fundamental wave having a first wavelength; an objective lens configured to focusing the fundamental wave on a sample surface; a wavelength filter configured to separate reflected light in which the fundamental wave is reflected from the sample from a signal light generated by irradiating the fundamental wave to the sample and having a second wavelength that is different from the first wavelength; and a detection unit configured to detect the signal light separated by the wavelength filter, wherein the detection unit is located to detect the signal light generated by the same fundamental wave in two or more different emission directions from the sample, the method including: generating the fundamental wave by the laser light source; focusing the fundamental wave on the sample surface using the objective lens; separating the reflected light from the signal light by the wavelength filter; and detecting the signal light by the detection unit.

In an embodiment, in the detecting of the signal light, the detection unit includes a detector configured to detect the intensity of the signal light on a pupil plane of the objective lens.

In an embodiment, in the detecting of the signal light, the detector is located at a conjugate position on the pupil plane of the objective lens and has a plurality of photosensitive surfaces.

In an embodiment, in the separating of the reflected light from the signal light, the second wavelength is half of the first wavelength.

In an embodiment, in the generating of the fundamental wave, the laser light source includes a pulse laser light source that generates the fundamental wave in a pulse form, and the pulse width of the fundamental wave is 1 picosecond or less.

In an embodiment, the semiconductor measurement device further includes a delay generator located between the laser light source and the objective lens on an optical path of the fundamental wave, and the semiconductor measurement method further includes generating the time difference for a portion of the fundamental wave to reach the sample with respect to another portion of the fundamental wave.

In an embodiment, in the generating of a time difference for a portion of the fundamental wave to reach the sample with respect to another portion, the delay generator includes a transmission member having a thickness distribution in an optical axis direction of the fundamental wave and generates the time difference according to a difference in optical path length of the fundamental wave passing through the transmission member.

In an embodiment, in the generating of a time difference for a portion of the fundamental wave to reach the sample with respect to another portion, the delay generator includes a reflective member having a height distribution in the optical axis direction of the fundamental wave and generates the time difference according to the difference in the optical path length of the fundamental wave reflected from the reflective member.

In an embodiment, in the detecting of the signal light, the detection unit includes a detector that detects the signal light generated by the fundamental wave with the time difference at every time difference in a dividing manner.

In an embodiment, in the detecting of the signal light, the detection unit includes a detector having a plurality of photosensitive surfaces, the number of photosensitive surfaces is equal to the number of time differences occurring in the delay generator, and each photosensitive surface receives the signal light to correspond to the signal light at every time difference.

In an embodiment, the semiconductor measurement device further includes a polarization controller located between the laser light source and the objective lens on the optical path of the fundamental wave, the semiconductor measurement method further includes controlling a polarization state of the fundamental wave by the polarization controller, and in the detecting of the signal light, the detection unit includes a detector configured to detect the signal light and a polarization analyzer configured to analyze the polarization state.

In an embodiment, in the detecting of the signal light, the polarization analyzer generates an interference pattern reflecting the polarization state of the signal light on the detector.

In an embodiment, in the controlling of the polarization state of the fundamental wave, the polarization controller generates a certain polarization state on the pupil plane of the objective lens.

In an embodiment, in the controlling of the polarization state of the fundamental wave, a certain polarization distribution includes any one of radial polarization, azimuthal polarization, and a combination of radial polarization and azimuthal polarization.

In an embodiment, the semiconductor measurement device further includes a light splitting unit located between the laser light source and the objective lens on the optical path of the fundamental wave, and the semiconductor measurement method further includes splitting the fundamental wave into two or more optical paths by the light splitting unit and adjusting optical path lengths of the split optical paths.

In an embodiment, in the adjusting of the optical path length of the split optical path, the light splitting unit includes a beam splitter configured to split the fundamental wave into equal amplitude parts and a mirror configured to reflect the fundamental wave.

In an embodiment, in the separating of the reflected light from the signal light, the wavelength filter includes a dichroic mirror, and in the detecting of the signal light, the detection unit is a first detection unit, and the semiconductor measurement device further includes a second detection unit configured to detect the reflected light separated from the signal light by the dichroic mirror.

In an embodiment, in the detecting of the signal light, the second detection unit includes a detector configured to detect the intensity of the fundamental wave, and a polarization analyzer configured to generate an interference pattern reflecting the polarization state of the fundamental wave on the detector.

In an embodiment, the semiconductor measurement device further includes a spatial phase modulator located between the laser light source and the objective lens on the optical path of the fundamental wave, and the semiconductor measurement method further includes controlling the polarization state of the fundamental wave by the spatial phase modulator.

In an embodiment, in the focusing of the fundamental wave on the sample surface, the optical axis of the objective lens is orthogonal to the sample surface.

The semiconductor measurement device of the present embodiment may eliminate the influence of temporal evolution by acquiring azimuth dependency collectively, and significantly improve measurement precision significantly by applying a high-precision method that allows measuring temporal evolution for each azimuth.

While the inventive concept has been particularly shown and described with reference to embodiments thereof, it will be understood that various changes in form and details may be made therein without departing from the spirit and scope of the following claims.

1. A semiconductor measurement device comprising:
a laser light source configured to generate a fundamental wave having a first wavelength;
an objective lens configured to focus the fundamental wave on a sample surface of a sample;
a wavelength filter configured to block reflected light corresponding to the fundamental wave that is reflected from the sample surface and transmit signal light generated by irradiating the fundamental wave to the sample surface; and
a first detection unit configured to detect the signal light passing through the wavelength filter,
wherein the first detection unit is located to detect the signal light generated from the sample surface and measures an intensity distribution of the signal light emitted in two or more different emission directions from the sample surface of the sample placed at a fixed position, and
wherein the signal light includes nonlinear light generated from the sample surface irradiated by the fundamental wave and having a second wavelength which is different from the first wavelength.

2. The semiconductor measurement device of claim 1,
wherein the first detection unit includes a first detector configured to detect an intensity of the signal light at a pupil plane of the objective lens.

3. The semiconductor measurement device of claim 2,
wherein the first detector is configured to receive the signal light at a conjugate position of the pupil plane of the objective lens and includes a plurality of photo sensors.

4. (canceled)

5. The semiconductor measurement device of claim 1,
wherein the laser light source includes a pulse laser light source configured to generate the fundamental wave which is a pulse-type fundamental wave, and
wherein a pulse width of the fundamental wave is 1 picosecond or less.

6. The semiconductor measurement device of claim 1, further comprising:
a delay generator located between the laser light source and the objective lens at an optical path of the fundamental wave,
wherein the delay generator generates a time difference between when a part of the fundamental wave reaches the sample surface and when another part of the fundamental wave reaches the sample surface.

7. The semiconductor measurement device of claim 6,
wherein the delay generator includes a transmission member having a thickness distribution in an optical axis direction of the fundamental wave and generates the time difference according to a difference in an optical path length of the fundamental wave passing through the transmission member.

8. The semiconductor measurement device of claim 6,
wherein the delay generator includes a reflective member having a height distribution in an optical axis direction of the fundamental wave and generates the time difference according to a difference in an optical path length of the fundamental wave reflected from the reflective member.

9. The semiconductor measurement device of claim 6,
wherein the first detection unit includes a first detector configured to detect the signal light generated by the fundamental wave having the time difference by distinguishing signal light for each time difference.

10. The semiconductor measurement device of claim 6,
wherein the delay generator is configured to generate a plurality of time differences of the fundamental wave passing through the delay generator,
wherein the first detection unit includes a first detector having a plurality of photo sensors,
wherein a number of photo sensors is equal to a number of a plurality of time differences occurring in the delay generator, and
wherein each photo sensor of the plurality of photo sensors receives the signal light at a corresponding time difference of the plurality of time differences.

11. The semiconductor measurement device of claim 1, further comprising
a polarization controller located between the laser light source and the objective lens at an optical path of the fundamental wave,
wherein the polarization controller controls a polarization state of the fundamental wave, and
wherein the first detection unit includes a first detector configured to detect the signal light and a first polarization analyzer configured to analyze a polarization state of the signal light.

12. The semiconductor measurement device of claim 11,
wherein the first polarization analyzer is configured to generate an interference pattern reflecting the polarization state of the signal light and provide the interference pattern of the signal light to the first detector.

13. The semiconductor measurement device of claim 11,
wherein the polarization controller is configured to generate a certain polarization state of the fundamental wave at a pupil plane of the objective lens.

14. (canceled)

15. The semiconductor measurement device of claim 1, further comprising:
an annular light shaper located between the laser light source and the objective lens at an optical path of the fundamental wave,
wherein the annular light shaper is configured to shape the fundamental wave into an annular shape.

16. The semiconductor measurement device of claim 1, further comprising:
a light splitting unit located between the laser light source and the objective lens at an optical path of the fundamental wave,
wherein the light splitting unit is configured to split the fundamental wave into two or more optical paths and adjust optical path lengths of the two or more optical paths.

17. (canceled)

18. The semiconductor measurement device of claim 1,
wherein the wavelength filter includes a dichroic mirror, and
wherein the semiconductor measurement device further comprises a second detection unit configured to detect the reflected light reflected by the dichroic mirror.

19. (canceled)

20. The semiconductor measurement device of claim 1, further comprising:
a spatial phase modulator located between the laser light source and the objective lens at an optical path of the fundamental wave.

21. (canceled)

22. A semiconductor measurement device comprising:
a laser light source configured to generate a fundamental wave, which is a pulse-type fundamental wave, having a first wavelength;
an objective lens configured to focus the fundamental wave on a sample surface of a sample;
an annular light shaper located between the laser light source and the objective lens at an optical path of the fundamental wave and configured to shape the fundamental wave into an annular shape;
a delay generator located between the laser light source and the objective lens at the optical path of the fundamental wave and configured to generate a time difference between when a part of the fundamental wave reaches the sample surface and when another part of the fundamental wave reaches the sample surface;
a polarization controller located between the laser light source and the objective lens at the optical path of the fundamental wave and configured to control a polarization state of the fundamental wave;
a wavelength filter configured to block reflected light corresponding to the fundamental wave that is reflected from the sample surface and transmit signal light generated by irradiating the fundamental wave to the sample surface; and
a detection unit including a detector located at a conjugate position of a pupil plane of the objective lens and configured to detect the signal light transmitted by the wavelength filter,
wherein the detection unit is located to detect the signal light generated from the sample surface and measures an intensity distribution of the signal light emitted in two or more different emission directions from the sample surface of the sample placed at a fixed position, and
wherein the signal light includes nonlinear light generated from the sample surface irradiated by the fundamental wave and having a second wavelength which is different from the first wavelength.

23. The semiconductor measurement device of claim 22,
wherein the delay generator includes a transmission member having a thickness distribution in an optical axis direction of the fundamental wave and generates the time difference according to a difference in an optical path length of the fundamental wave passing through the transmission member.

24.-26. (canceled)

27. A semiconductor measurement device comprising:
a laser light source configured to generate a fundamental wave, which is a pulse-type fundamental wave, having a first wavelength;
an objective lens configured to focus the fundamental wave on a sample surface of a sample;
a polarization controller located between the laser light source and the objective lens at an optical path of the fundamental wave and configured to control a polarization state of the fundamental wave;
a wavelength filter configured to block reflected light corresponding to the fundamental wave that is reflected from the sample surface and transmit signal light generated by irradiating the fundamental wave to the sample surface and having a second wavelength that is different from the first wavelength; and
a detection unit including a detector located at a conjugate position of a pupil plane of the objective lens and detecting the signal light transmitted by the wavelength filter,
wherein the detection unit is located to detect the signal light generated from the sample surface and measures an intensity distribution of the signal light emitted in two or more different emission directions from the sample surface of the sample placed at a fixed position, and
wherein the signal light includes nonlinear light generated from the sample surface irradiated by the fundamental wave.

28. The semiconductor measurement device of claim 27, further comprising:
a light splitting unit located between the laser light source and the objective lens at the optical path of the fundamental wave and configured to split the fundamental wave into two or more optical paths and adjust optical path lengths of the two or more optical paths,
wherein the light splitting unit includes a beam splitter configured to split the fundamental wave into two parts having an equal amplitude and a mirror configured to reflect one of the two parts of the fundamental wave.

29. (canceled)
